(19) United States
(12) Patent Application Publication
(10) Pub. No.: US 2023/0178643 A1
(43) Pub. Date: Jun. 8, 2023

(54) HIGH ELECTRON MOBILITY TRANSISTOR DEVICE

(71) Applicant: Industrial Technology Research Institute, Hsinchu (TW)

(72) Inventors: Shih-Chin Lin, Taipei City (TW); Ching-Chiun Wang, Miaoli County (TW); Jwu-Sheng Hu, Hsinchu County (TW); Yi Chang, Hsinchu County (TW); Yi-Jiun Lin, Chiayi County (TW)

(73) Assignee: Industrial Technology Research Institute, Hsinchu (TW)

(21) Appl. No.: 17/561,633

(22) Filed: Dec. 23, 2021

(30) Foreign Application Priority Data
Dec. 8, 2021 (TW) 110145951

(51) Int. Cl. H01L 29/778; H01L 29/15; H01L 29/20; H01L 29/205

(52) U.S. Cl. CPC H01L 29/7785; H01L 29/155; H01L 29/2003; H01L 29/205

(57) ABSTRACT

A high electron mobility transistor (HEMT) device includes at least an AlN nucleation layer, a superlattice composite layer, a GaN electron transport layer, and an AlGaN barrier layer. The superlattice composite layer is disposed on the AlN nucleation layer, and the superlattice composite layer includes a plurality of AlN films and a plurality of GaN films stacked alternately to reduce device stress. The GaN electron transport layer is disposed on the superlattice composite layer, and the AlGaN barrier layer is disposed on the GaN electron transport layer.

### CROSS-REFERENCE TO RELATED APPLICATION

This application claims the priority benefit of Taiwan application serial no. 110145951, filed on Dec. 8, 2021. The entirety of the above-mentioned patent application is hereby incorporated by reference herein and made a part of this specification.

### TECHNICAL FIELD

The disclosure relates to a high electron mobility transistor (HEMT) device.

### BACKGROUND

In a group-III nitride high electron mobility transistor (HEMT), due to its strong polarization and piezoelectric effects, two-dimensional electron gas (2DEG) with high carrier density is produced. The 2DEG refers to the phenomenon that electron gas may move freely in a two-dimensional direction, but is restricted in a third-dimensional direction. Therefore, carrier/electron migration velocity of the transistor may be significantly improved.

At present, a gallium nitride (GaN) HEMT has great potential when it is applied on high-frequency and high-power conditions because of its current stability and its ability to withstand a high breakdown voltage, but structural defects and epitaxial film stress may easily deteriorate said characteristics.

### SUMMARY

In an embodiment of the disclosure, a HEMT device includes at least an AlN nucleation layer, a superlattice composite layer, a GaN electron transport layer, and an AlGaN barrier layer. The superlattice composite layer is disposed on the AlN nucleation layer, and the superlattice composite layer includes several AlN films and several GaN films stacked alternately. The GaN electron transport layer is disposed on the superlattice composite layer, and the AlGaN barrier layer is disposed on the GaN electron transport layer.

In another embodiment of the disclosure, a HEMT device includes at least an AlN nucleation layer, a superlattice composite layer, a GaN electron transport layer, and an AlGaN barrier layer. The superlattice composite layer is disposed on the AlN nucleation layer, and the superlattice composite layer includes several first films and several second films stacked alternately; here, materials of the first films and the second films are represented as AlₓGa_{y}In_{z}N, x, y, and z each have a value of 0 to 1, and x+y+z=1. A thickness of each of the first films is between 10 nm and 30 nm, and a thickness of each of the second films is between 10 nm and 30 nm. The GaN electron transport layer is disposed on the superlattice composite layer, and the AlGaN barrier layer is disposed on the GaN electron transport layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional view of a high electron mobility transistor (HEMT) device according to an embodiment of the disclosure.

FIG. 2 is a schematic cross-sectional view of a HEMT device according to another embodiment of the disclosure.

FIG. 3 illustrates breakdown voltage values of the HEMT device provided in a comparison example, which are measured at different measurement point.

FIG. 4 illustrates breakdown voltage values of the HEMT device provided in an experimental example 1, which are measured at different measurement points.

FIG. 5 illustrates breakdown voltage values of the HEMT device provided in an experimental example 2, which are measured at different measurement points.

### DETAILED DESCRIPTION OF DISCLOSED EMBODIMENTS

The accompanying drawings in the following embodiments serve to describe the embodiments of the disclosure in a more comprehensive manner, while the HEMT device provided herein may be implemented in many different forms and should not be subject to the embodiments described herein. The terms “include”, “comprise”, “have”, and so on used in the disclosure are all open-ended terms and mean “include but are not limited to”. In addition, for clarity, relative distances, sizes, and positions of each film and layer may be scaled down or enlarged.

The disclosure provides a high electron mobility transistor (HEMT) device that may reduce a stress of epitaxial films to resolve issues of epitaxial structural defects and high voltage stability problems.

The disclosure also provides a HEMT device that may suppress defective structures, such as faults, dislocations, and lattice mismatch, so that an epitaxial stress of an electron transport layer is reduced, and the overall electrical performance is improved.

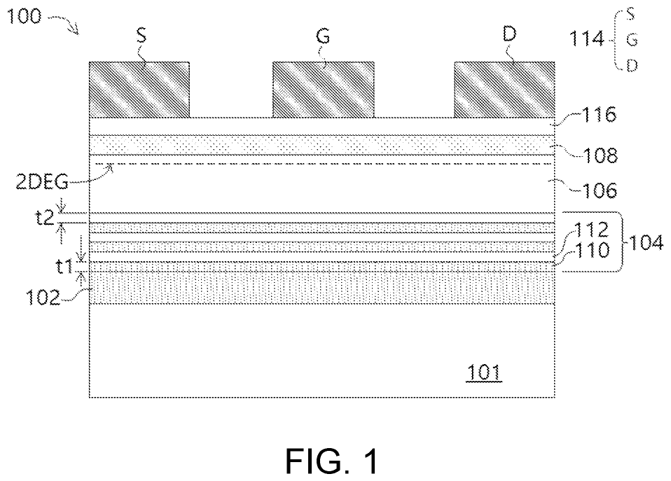

FIG. 1 is a schematic cross-sectional view of a high electron mobility transistor (HEMT) device according to an embodiment of the disclosure.

With reference to FIG. 1, a HEMT device 100 provided in this embodiment substantially includes an AlN nucleation layer 102, a superlattice composite layer 104, a GaN electron transport layer 106, and an AlGaN barrier layer 108. Each layer in the HEMT device 100 is grown through epitaxial processes, such as metal organic chemical vapor deposition (MOCVD), molecular beam epitaxy (MBE), hydride vapor phase epitaxy (HYPE), liquid phase epitaxy (LPE), and other epitaxial processes. The superlattice composite layer 104 is disposed on the AlN nucleation layer 102, and the superlattice composite layer 104 includes several AlN films 110 and several GaN films 112 stacked alternately. In the superlattice composite layer 104, a thickness t1 of each AlN film 110 is, for instance, 5 nm to 30 nm or 10 nm to 30 nm, and a thickness t2 of each GaN film 112 is, for instance, 5 nm to 30 nm or 10 nm to 30 nm. From the perspective of the degree of lattice mismatch, the thickness t2 of each GaN film 112 in the superlattice composite layer 104 is consistent with the thickness t1 of each AlN films 110. If the thickness is inconsistent, lattice mismatch stress of GaN films 112 and AlN films 110 may increase. Moreover, the number of films of the superlattice composite layer 104 is greater than or equal to 4, e.g., 4 to 16, 4 to 12, or 4 to 10. If the number of films of the superlattice composite layer 104 is more than 4, the problem of lattice mismatch may be resolved to reduce the stress; if the number of films of the superlattice composite layer 104 is less than 10, errors in the thickness of each resultant film may be reduced, and interface planarity may be monitored and controlled. Besides, a nucleation grain size of the AlN films 110 and the GaN films 112 is, for instance, equal to or less than 3 nm.

As shown in FIG. 1. a thickness of the GaN electron transport layer 106 disposed on the superlattice composite layer 104 is, for instance, 1 μm to 3 μm. A thickness of the AlGaN barrier layer 108 disposed on the GaN electron transport layer 106 is, for instance, 200 nm to 500 nm. Therefore, two-dimensional electron gas (2DEG) is generated near the interface between the GaN electron transport layer 106 and the AlGaN barrier layer 108.

In FIG. 1, the AlN nucleation layer 102 and the superlattice composite layer 104 are in direct contact, and the superlattice composite layer 104 and the GaN electron transport layer 106 are in direct contact, however which should not be construed as limitations in the disclosure. Since the AlN films 110 and the GaN films 112 alternately stacked in the superlattice composite layer 104 may suppress defective structures, such as faults, dislocations, and lattice mismatch, the stress of the GaN electron transport layer 106 epitaxially grown above the superlattice composite layer 104 may be reduced. In detail, the total stress of the GaN electron transport layer 106 is usually equal to a sum of an intrinsic defect stress of the materials, a lattice mismatch stress of the superlattice composite layer 104, and a thermal stress generated in the epitaxial process. Hence, as long as the lattice mismatch stress of the superlattice composite layer 104 is reduced, the stress of the GaN electron transport layer 106 may be reduced accordingly, e.g., less than 0.3 GPa. As the stress of the GaN electron transport layer 106 is reduced, the breakdown voltage of the HEMT device 100 is raised to be greater than 2 kV, for instance.

With reference to FIG. 1, the HEMT device 100 further includes a substrate 101 located below the AlN nucleation layer 102, and the substrate 101 is, for instance, a sapphire substrate, a silicon substrate, a silicon carbide substrate, a gallium nitride (GaN) substrate, or any other substrate which may be applied in the epitaxial process. A thickness of the AlN nucleation layer 102 is, for instance, 20 nm to 30 nm. In addition, an electrode layer 114 and a cap layer 116 may be disposed on the AlGaN barrier layer 108, wherein the electrode layer 114 includes a gate G, a source S, and a drain D, and the gate G is disposed between the source S and the drain D. The cap layer 116 is located between the AlGaN barrier layer 108 and the electrode layer 114, wherein the cap layer 116 is, for instance, made of an n-type GaN, and a thickness of the cap layer 116 is, for instance, 20 nm to 40 nm.

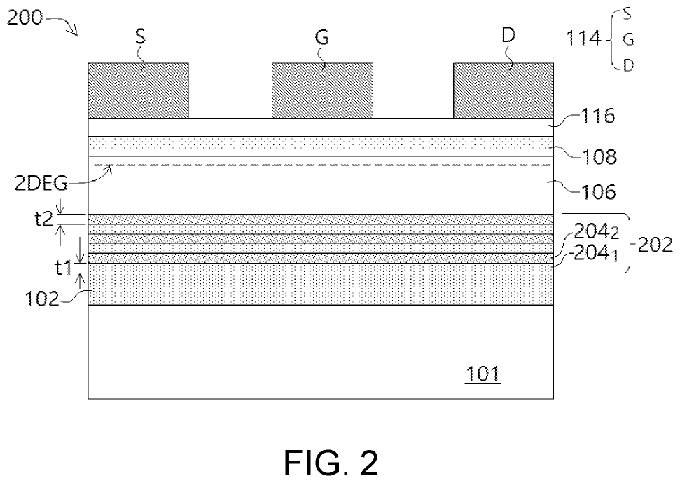

FIG. 2 is a schematic cross-sectional view of a HEMT device according to another embodiment of the disclosure. The reference numbers provided in the previous embodiment serve to represent the same or similar parts and components in this embodiment, and the related content of the same or similar parts and components may also be referred to as those provided in the previous embodiment and thus will not be further explained hereinafter.

With reference to FIG. 2, the difference between a HEMT device 200 provided in this embodiment and the HEMT device provided in the previous embodiment lies in that a superlattice composite layer 202 includes several first films 204₁ and several second films 204₂ stacked alternately, and the number of films of the superlattice composite layer 202 is, for instance, 4 or more, such as 4 to 10. The thickness t1 of each first film 204₁ is between 10 nm and 30 nm, and the thickness t2 of each second film 204₂ is between 10 nm and 30 nm. From the perspective of the degree of lattice mismatch, the thickness of the first film 204₁ and the second film 204₂ is consistent. Materials of the first films 204₁ and the second films 204₂ are respectively represented as AlₓGa_{y}In_{z}N, wherein x, y, and z each one independently have a value of 0 to 1, and x+y+z=1; besides, the first films 204₁ and the second films 204₂ are different. In an embodiment, the material of the first films 204₁ is AlN, and the material of the second films 204₂ is GaN. In another embodiment, the material of the first films 204₁ is AlₓGa_{y}N, wherein x+y=1, 0<x<0.5, and 0.5<y<1; the material of the second films 204₂ is In_{z}AlₓGa_{y}N, wherein x+y+z=1, 0<z<0.2, and 0<y<0.5. In still another embodiment, the material of the first films 204₁ and the material of the second films 204₂ are both AlₓGa_{y}N, but the aluminum content (x value) in the material of the first films 204₁ is greater than that (x value) in the material of the second films 204₂, and so on and so forth. In still another embodiment, the material of the first films 204₁ is AlₓGa_{y}N, and the material of the second films 204₂ is GaN, wherein x+y=1, 0<x<0.5, and 0.5<y<1.

In view of the above, the HEMT device provided in one or more embodiments of the disclosure includes the superlattice composite layer disposed between the AlN nucleation layer and the GaN electron transport layer, and therefore the defective structures including faults, dislocations, and lattice mismatch may be suppressed by alternately stacking films made of different materials in the superlattice composite layer. As such, the stress of the GaN electron transport layer epitaxially grown above the superlattice composite layer may be reduced, which may increase the breakdown voltage of the HEMT device, so as to resolve the issues of conventional HEMT epitaxial structural defects and high voltage stability problems.

Following experiments serve to verify the effects provided herein, while the following should not be construed as limitations in the disclosure.

### Comparison Example

First, an MOCVD process is performed to sequentially form an AlN nucleation layer (of which the thickness is 25 nm), a GaN electron transport layer (of which the thickness is 2 μm), an AlGaN barrier layer (of which the thickness is 250 nm), and a cap layer (of which the material is GaN and the thickness is 30 nm) on a sapphire substrate.

A Raman spectroscopy test, an X-ray diffractometer (XRD) analysis, an atomic force microscopy (AFM) surface topography mapping analysis for obtaining root mean square (RMS) roughness, and so on are performed on the resultant HEMT device to obtain results, which are shown in Table 1.

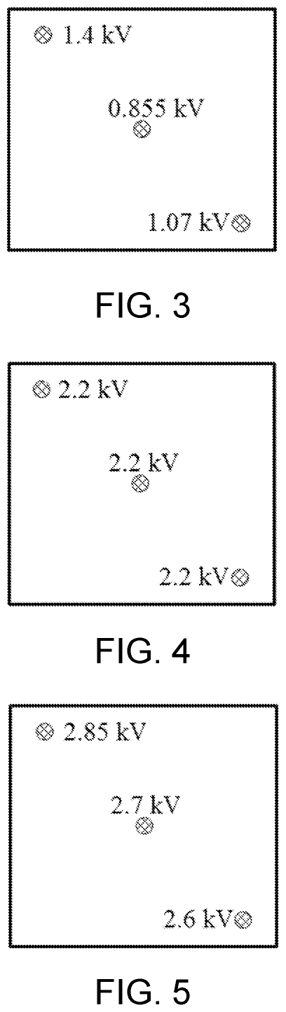

In addition, a breakdown voltage test is performed on the resultant HEMT device to obtain results, which are shown in FIG. 3 and Table 1. A model of machine configured to perform the breakdown voltage test is B1505A, an electrode test interval is 20 μm, and the test is conducted on the conditions that a start voltage is 0V, an end voltage is 3 kV, and a voltage interval of each test is 3V. FIG. 3 illustrates breakdown voltage values of the HEMT device provided in the comparison example, which are measured at different measurement point.

### Experimental Example 1

The HEMT device is formed by applying the method provided in the comparison example. However, after the AlN nucleation layer is formed and before the GaN electron transport layer is formed, the MOCVD process is performed to form a superlattice composite layer, which is composed of two AlN films and two GaN films stacked alternately, and the thickness of each film is about 10 nm.

Similarly, a Raman spectroscopy test, an XRD analysis, an AFM surface topography mapping analysis for obtaining RMS roughness, a breakdown voltage test, and so on are performed on the resultant HEMT device to obtain results, which are shown in Table 1. FIG. 4 illustrates breakdown voltage values of the HEMT device provided in the experimental example 1, which are measured at different measurement points.

### Experimental Example 2

The HEMT device is formed by applying the method provided in the experimental example 1, while the thickness of each film in the superlattice composite layer is changed to about 20 nm; hence, the total thickness of the superlattice composite layer is twice the thickness provided in the experimental example 1.

Similarly, a Raman spectroscopy test, an XRD analysis, an AFM surface topography mapping analysis for obtaining RMS roughness, a breakdown voltage test, and so on are performed on the resultant HEMT device to obtain results, which are shown in Table 1. FIG. 5 illustrates breakdown voltage values of the HEMT device provided in the experimental example 2, which are measured at different measurement points.

TABLE 1

| | Comparison | | Experimental | | Experimental | |
|---|---|---|---|---|---|---|
| | example | | example 1 | | example 2 | |
| Raman peak position | 571.47 | cm⁻¹ | 570.33 | cm⁻¹ | 569.58 | cm⁻¹ |
| Raman shift (Δω) | 2.86 | cm⁻¹ | 1.72 | cm⁻¹ | 0.97 | cm⁻¹ |
| (E2 Mode, the reference | | | | | | |
| point is 568.61) | | | | | | |
| Stress (GPa) | 0.461 | | 0.277 | (↓40%) | 0.156 | (↓67%) |
| (Δω = 6.2σ) | | | | | | |
| RMS roughness | 0.272 | nm | 0.204 nm | (↓25%) | 0.236 nm | (↓13%) |

| | | | | | |
|---|---|---|---|---|---|
| Quality of epitaxially grown | 146 | 114 | (↑22%) | 125 | (↑14%) |
| crystals | | | | | |
| Full width at half maximum | | | | | |
| (FWHM) GaN 002 (arc · sec) | | | | | |
| Breakdown voltage (kV) | 1.4 | 2.2 | (↑57%) | 2.85 | (↑103%) |

Remarks:
1) The percentage (%) in the parentheses is the rate of decrease or increase compared to the comparison example.
2) The stress is a numerical value converted according to the Raman spectra (with reference to “Thermal stress in GaN epitaxial layers grown on sapphire substrates” published in Journal of Applied Physics 77, 4389-4392 (1995) by T. Kozawa et al.).
3) The quality of epitaxially grown crystals is obtained by conducting the XRD analysis and is the FWHM of GaN 002 crystal plane.

According to Table 1, the results exhibit that the stress of the GaN electron transport layer in the structure provided herein is less than 0.3 GPa, and the stress is reduced by at least 40% in comparison with the stress in the comparison example. Moreover, in the structure provided herein, the surface roughness is relatively small (RMS <0.25 nm), the crystal quality is improved (GaN002<130 arc·sec), and the high withstand voltage characteristics are improved (the breakdown voltage is greater than 2.2 kV).

As shown in FIG. 3, FIG. 4, and FIG. 5, it may be learned that the breakdown voltage is greater than that in the comparison example, even though the breakdown voltage may be measured from different positions.

(Simulation Experiment)

The simulation experiment is conducted according to “Investigation of coherency stress-induced phase separation in AlN/AlₓGa₁₋ₓN superlattices grown on sapphire substrates” published in Royal Society of Chemistry, vol. 22, pp. 3198-3205, 2020 by W. Yao et al. and “Reversible stress changes at all stages of Volmer-Weber film growth” published in Journal of Applied Physics, vol. 95 pp. 1010-1020, 2003 by C. Friesen et al. The lattice mismatch stress is calculated as follows. Here, films of a multi-film layer are isotropic on a plane parallel to the substrate, and interfaces between the films do not affect one another. On the condition of the known average stress in one single film, a primary formula of calculating the stress in the layer formed by alternately depositing two types of films made of materials A and B is as follows:

$$σ = \frac{{d}_{A}}{t} {σ}_{A} + \frac{{d}_{B}}{t} {σ}_{B} + \frac{N}{2} ( {f}^{AB} + {f}^{BA} )$$

Here, σ is a stress of films of a multi-film layer, N is the number of interfaces of two materials, t is a periodic geometric thickness of the films, dA and dB are respectively a geometric thickness of two films in the period, σA and σB are respectively an average stress of the two materials A and B when the materials A and B are individually deposited, and f^{AB} and f^{BA} are respectively an interfacial stress.

### Simulation Experimental Examples 1˜6

According to the simulation experiment, the thickness and the number of films of the superlattice composite layer in the simulated device are changed, as shown in Table 2 to Table 7. A simulation software ANSYS is then applied to obtain a strain and convert the strain into the stress according to the literature mentioned in the simulation comparison examples. The results are also shown in Table 2 to Table 7.

TABLE 2

| | | | Lattice | | | |
|---|---|---|---|---|---|---|
| | | Thick- | constant (Å) | | | |
| Simulated | | ness | i | (i-1) | | Stress |
| structure | | (nm) | layer | layer | Strain | (MPa) |
| GaN electron | | 2000 | 3.188 | | 0.00159 | 625 |
| transport layer | | | | | | |
| Super- | GaN | 5 | 3.188 | 3.186 | 0.02337 | |
| lattice | AlN | 5 | 3.112 | 3.115 | −0.02319 | |
| composite | GaN | 5 | 3.188 | 3.186 | 0.02442 | |
| layer | AlN | 5 | 3.112 | 3.112 | 0 | |

| | | |
|---|---|---|
| AlN nucleation | 100 | 3.112 |
| layer | | |

Remarks: The i layer in Table 2 to Table 7 refers to the i-th layer, and the (i-1) layer refers to the layer below the i-th layer.

TABLE 3

| | | | Lattice | | | |
|---|---|---|---|---|---|---|
| | | Thick- | constant (Å) | | | |
| Simulated | | ness | i | (i-1) | | Stress |
| structure | | (nm) | layer | layer | Strain | (MPa) |
| GaN electron | | 2000 | 3.188 | | 0.00108 | 496 |
| transport layer | | | | | | |
| Super- | GaN | 10 | 3.188 | 3.185 | 0.02258 | |
| lattice | AlN | 10 | 3.112 | 3.118 | −0.02263 | |
| composite | GaN | 10 | 3.188 | 3.184 | 0.02442 | |
| layer | AlN | 10 | 3.112 | 3.112 | 0 | |

| | | |
|---|---|---|
| AlN nucleation | 100 | 3.112 |
| layer | | |

TABLE 4

| | | | Lattice | | | |
|---|---|---|---|---|---|---|
| | | Thick- | constant (Å) | | | |
| Simulated | | ness | i | (i-1) | | Stress |
| structure | | (nm) | layer | layer | Strain | (MPa) |
| GaN electron | | 2000 | 3.188 | | 0.00105 | 553 |
| transport layer | | | | | | |
| Super- | GaN | 20 | 3.188 | 3.183 | 0.02150 | |
| lattice | AlN | 20 | 3.112 | 3.121 | −0.02171 | |
| composite | GaN | 20 | 3.188 | 3.181 | 0.02442 | |
| layer | AlN | 20 | 3.112 | 3.112 | 0 | |

| | | |
|---|---|---|
| AlN nucleation | 100 | 3.112 |
| layer | | |

TABLE 5

| Simulated | | Thickness | Lattice constant (Å) | | | stress |
|---|---|---|---|---|---|---|
| structure | | (nm) | i layer | (i-1) layer | strain | (MPa) |
| GaN electron | | 2000 | 3.188 | | 0.00082 | 487 |
| transport layer | | | | | | |
| Super- | GaN | 5 | 3.188 | 3.186 | 0.02350 | |
| lattice | AlN | 5 | 3.112 | 3.115 | −0.02330 | |
| composite | GaN | 5 | 3.188 | 3.186 | 0.02344 | |
| layer | AlN | 5 | 3.112 | 3.115 | −0.02326 | |
| | GaN | 5 | 3.188 | 3.186 | 0.02337 | |
| | AlN | 5 | 3.112 | 3.115 | −0.02319 | |
| | GaN | 5 | 3.188 | 3.186 | 0.02442 | |
| | AlN | 5 | 3.112 | 3.112 | 0.00000 | |

| | | |
|---|---|---|
| AlN nucleation | 100 | 3.112 |
| layer | | |

TABLE 6

| | | | Lattice | | | |
|---|---|---|---|---|---|---|
| | | Thick- | constant (Å) | | | |
| Simulated | | ness | i | (i-1) | | Stress |
| structure | | (nm) | layer | layer | Strain | (MPa) |
| GaN electron | | 2000 | 3.188 | | 0.00103 | 548 |
| transport layer | | | | | | |
| Super- | GaN | 10 | 3.188 | 3.172 | −0.01181 | |
| lattice | Al_{0.2}Ga_{0.8}N | 10 | 3.173 | 3.131 | 0.02471 | |
| composite | GaN | 10 | 3.188 | 3.167 | −0.01092 | |
| layer | Al_{0.2}Ga_{0.8}N | 10 | 3.173 | 3.127 | 0.02033 | |

| | | |
|---|---|---|
| AlN nucleation | 100 | 3.112 |
| layer | | |

TABLE 7

| | | | Lattice | | | |
|---|---|---|---|---|---|---|
| | | Thick- | constant (Å) | | | |
| Simulated | | ness | i | (i-1) | | Stress |
| structure | | (nm) | layer | layer | Strain | (MPa) |
| GaN electron | | 2000 | 3.188 | 3.185 | 0.00173 | 684 |
| transport layer | | | | | | |
| Super- | GaN | 10 | 3.188 | 3.184 | 0.02382 | |
| lattice | AlN | 5 | 3.112 | 3.115 | −0.02257 | |
| composite | GaN | 10 | 3.188 | 3.185 | 0.02442 | |
| layer | AlN | 5 | 3.112 | 3.112 | 0.00000 | |

| | | | |
|---|---|---|---|
| AlN nucleation | 100 | 3.112 | 3.112 |
| layer | | | |

It may be derived from Table 2 to Table 7 that the thickness and the number of films of the superlattice composite layer may lead to changes to the stress of the GaN electron transport layer, thereby affecting the electrical properties of the HEMT device.

To sum up, the superlattice composite layer provided in one or more embodiments of the disclosure has two films which are made of different materials and are alternately stacked, which may suppress defective structures, such as faults, dislocations, and lattice mismatch, and therefore the stress of the overlying GaN electron transport layer grown on the superlattice composite layer may be reduced. As such, the breakdown voltage of the HEMT device is improved.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A high electron mobility transistor device, comprising:
an AlN nucleation layer;
a superlattice composite layer, disposed on the AlN nucleation layer, wherein the superlattice composite layer comprises a plurality of AlN films and a plurality of GaN films stacked alternately;
a GaN electron transport layer, disposed on the superlattice composite layer; and
an AlGaN barrier layer, disposed on the GaN electron transport layer.

2. The high electron mobility transistor device according to claim 1, wherein a thickness of each of the GaN films is between 5 nm and 30 nm, and a thickness of each of the AlN films is between 5 nm and 30 nm.

3. The high electron mobility transistor device according to claim 1, wherein a thickness of each of the GaN films in the superlattice composite layer is consistent with a thickness of each of the AlN films.

4. The high electron mobility transistor device according to claim 1, wherein the AlN nucleation layer and the superlattice composite layer are in direct contact, and the superlattice composite layer and the GaN electron transport layer are in direct contact.

5. The high electron mobility transistor device according to claim 1, wherein the number of films of the superlattice composite layer is 4 to 10.

6. The high electron mobility transistor device according to claim 1, wherein a stress of the GaN electron transport layer is less than 0.3 GPa.

7. The high electron mobility transistor device according to claim 1, wherein a breakdown voltage of the high electron mobility transistor device is greater than 2 kV.

8. The high electron mobility transistor device according to claim 1, further comprising a substrate located below the AlN nucleation layer.

9. The high electron mobility transistor device according to claim 1, further comprising:
an electrode layer, located on the AlGaN barrier layer, wherein the electrode layer comprises a gate, a source, and a drain, and the gate is disposed between the source and the drain; and
a cap layer, located between the AlGaN barrier layer and the electrode layer.

10. A high electron mobility transistor device, comprising:
an AlN nucleation layer;
a superlattice composite layer, disposed on the AlN nucleation layer, wherein the superlattice composite layer comprises a plurality of first films and a plurality of second films stacked alternately, and materials of the first films and the second films are each represented by AlₓGa_{y}In_{z}N, wherein x, y, and z each one independently have a value of 0 to 1, and x+y+z=1, wherein a thickness of each of the first films is between 10 nm and 30 nm, and a thickness of each of the second films is between 10 nm and 30 nm;
a GaN electron transport layer, disposed on the superlattice composite layer; and
an AlGaN barrier layer, disposed on the GaN electron transport layer.

11. The high electron mobility transistor device according to claim 10, wherein the thickness of the first films is consistent with the thickness of the second films.

12. The high electron mobility transistor device according to claim 10, wherein the material of the first films is AlN, and the material of the second films is GaN.

13. The high electron mobility transistor device according to claim 10, wherein the material of the first films is AlₓGa_{y}N, and the material of the second films is Ga_{y}In_{z}N.

14. The high electron mobility transistor device according to claim 10, wherein the AlN nucleation layer and the superlattice composite layer are in direct contact, and the superlattice composite layer and the GaN electron transport layer are in direct contact.

15. The high electron mobility transistor device according to claim 10, wherein the number of films of the superlattice composite layer is 4 to 10.

16. The high electron mobility transistor device according to claim 10, wherein a stress of the GaN electron transport layer is less than 0.3 GPa.

17. The high electron mobility transistor device according to claim 10, wherein a breakdown voltage of the high electron mobility transistor device is greater than 2 kV.

18. The high electron mobility transistor device according to claim 10, further comprising a substrate located below the AlN nucleation layer.

19. The high electron mobility transistor device according to claim 10, further comprising:
an electrode layer, located on the AlGaN barrier layer, wherein the electrode layer comprises a gate, a source, and a drain, and the gate is disposed between the source and the drain; and
a cap layer, located between the AlGaN barrier layer and the electrode layer.
